(19) United States
(12) Patent Application Publication
(10) Pub. No.: US 2011/0168970 A1
(43) Pub. Date: Jul. 14, 2011

(54) OPTOELECTRONIC LIGHT EMITTING STRUCTURE

(75) Inventors: Zoran Salcic, Takapuna (NZ); Fei Chen, Auckland (NZ); Wei Gao, Birkenhead (NZ); Wong C. Cheong, Singapore (SG); Franck Chollet, Singapore (SG)

(73) Assignee: AUCKLAND UNISERVICES LIMITED, Auckland (NZ)

(21) Appl. No.: 12/920,950

(22) PCT Filed: Mar. 5, 2009
(86) PCT No.: PCT/NZ09/00028

§ 371 Date: Mar. 28, 2011

Related U.S. Application Data
(60) Provisional application No. 61/034,883, filed on Mar. 7, 2008.

(51) Int. Cl. H01L 33/06; H01L 33/26

(52) U.S. Cl. 257/13; 257/43; 438/47; 257/E33.003; 257/E33.013; 257/E33.048

(57) ABSTRACT

A light emitting structure comprising a hot electron source and a layer of ptoelectronic material disposed thereon and optionally p-type material disposed on the optoelectronic material. For example, a light emitting structure that comprises, in order, a polycrystalline silicon layer, a silicon dioxide layer, a zinc oxide layer and an indium tin oxide (ITO) layer. When a sufficient voltage is applied across the layers, light is generated.

### TECHNICAL FIELD

The invention relates to light emitting structures, in particular to on-chip ZnO-ITO light emitting structures, to the methods of preparation of such structures, and to their uses.

### BACKGROUND

Silicon (Si) is the backbone of the modern computer industry. The power and size of computers has improved exponentially every year from the 1960's primarily as a result of reducing the size of integrated circuits. Moore's law states that the number of transistors that can be placed on an integrated circuit doubles every year. Such a situation is subject to certain physical constraints and cannot continue indefinitely. In fact, conventional computer circuitry is fast approaching the limits of Moore's law. The conducting paths in modern circuits are now about 45 nm with the absolute physical limit predicted to be around 10 or 11 nm. Realising the full extent and power of very large scale integration is also currently not possible since there are considerable interconnect bottlenecks in current chips.

Continuing increases in power and decrease in size are thus unlikely to continue beyond the near future if current technologies alone are used. Scientists the world over are looking for new ways to continue the advancement of computer technology and enable such applications as, for example, real-time natural language translation, automatic facial recognition or intelligent automatic chauffeuring involving communication with a vehicle using voice and vision systems.

Photonic computing, that is computing using light to process and transmit signals within integrated circuits, is believed to be a promising direction for providing increases in computer speed and power. Because photonic computing is based upon photons, rather than electrons, it has certain inherent advantages—in particular, photons move much faster than electrons, and have inherently higher bandwidths (data carrying capacities).

In order to implement photonic computing, it is necessary to achieve light emission from Si based integrated circuits. Current light emitting devices are mainly made from III-V semiconductor compounds such as GaAs, GaN, GaP, InP, InAs, InGaAs, InGaAsP and the like. These light emitting compounds are, however, difficult to integrate into Si chips.

The concept of Si based light emission is not new, but it has previously proved very difficult to achieve in a simple, reliable and robust way. Recent approaches have been complicated, for example involving anti-crossing between coupled Si rings, and even that approach has not produced entirely satisfactory results.

Accordingly, it is an object of the present invention to overcome or ameliorate at least one of the disadvantages of the prior art, or to provide a useful alternative.

Any discussion of the prior art throughout the specification should in no way be considered as an admission that such prior art is widely known or forms part of common general knowledge in the field.

### SUMMARY OF THE INVENTION

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

According to a first aspect the invention provides a light emitting structure that comprises a hot electron source and a layer of optoelectronic material disposed thereon.

According to a second aspect the invention provides a light emitting structure that comprises a hot electron source; a layer of optoelectronic material disposed on the hot electron source; and p-type material disposed on the optoelectronic material.

The hot electron source preferably comprises a single crystal silicon substrate, a polycrystalline silicon layer disposed thereon; and a layer of silicon oxide disposed on the polycrystalline silicon layer. Alternatively, the hot electron source may comprise a suitable substrate, such as single crystal silicon having an aluminium or magnesium layer disposed thereon, with a corresponding layer of aluminium oxide or magnesium oxide disposed on the aluminium or magnesium layer. In this document the hot electron emitting structure (substrate) is referred to as HEES.

The optoelectronic material is preferably Zinc oxide (ZnO).

The p-type material is preferably optically transparent. One highly preferred p-type material is a layer of indium tin oxide (ITO).

In a preferred aspect, the invention provides a light emitting structure that comprises a hot electron source and a zinc oxide layer disposed thereon.

In an even more preferred aspect, the invention provides a light emitting structure that comprises a hot electron source, a zinc oxide layer disposed thereon; and an indium tin oxide (ITO) layer disposed on the zinc oxide layer.

The light emitting structures of the present invention may also include a voltage source to apply a voltage across the HEES and optoelectronic material.

In one particularly preferred aspect the invention provides a light emitting structure that comprises, in order, the following layers:

a polycrystalline silicon layer;
a silicon dioxide layer; and
a zinc oxide layer.

In an even more preferred aspect the invention provides a light emitting structure that comprises, in order, the following layers:

a polycrystalline silicon layer;
a silicon dioxide layer;
a zinc oxide layer; and
an indium tin oxide (ITO) layer.

Preferably, the invention provides a light emitting structure that comprises, in order, the following layers:

a single crystal silicon substrate;
a polycrystalline silicon layer;
a silicon dioxide layer; and
a zinc oxide layer

Most preferably the invention provides a light emitting structure that comprises, in order, the following layers:

a single crystal silicon substrate;
polycrystalline silicon layer;
a silicon dioxide layer;
a zinc oxide layer; and
an indium tin oxide (ITO) layer

Preferably the single crystal silicon substrate and the polycrystalline are doped such that they are both n-type or p-type doped. Preferably they are heavily doped.

Thus, in one preferred embodiment, the single crystal silicon substrate and the polysilicon layer are both doped to be n-type silicon (electrons).

In an alternative, equally preferred embodiment, the single crystal silicon substrate and the polysilicon layer are both doped to be p-type silicon (holes)

One embodiment of the invention provides a light emitting structure that, when subject to voltage, displays a current vs voltage curve that has a current at a predetermined voltage sufficient to generate light.

In another embodiment the invention provides a light emitting structure that, when subject to voltage, displays at least one current peak on a current vs voltage curve that has a current at a predetermined voltage sufficient to generate light.

In another embodiment the invention provides a light emitting structure that, when subject to voltage, displays two current peaks on a current vs voltage curve, that has a current at two predetermined voltages sufficient to generate light and a region intermediate said peaks which has a current insufficient to generate light.

In another embodiment the invention provides a light emitting structure that, when subject to voltage, displays multiple current peaks on a current vs voltage curve, wherein the peaks correspond to a predetermined voltage sufficient to generate light, and wherein there are regions intermediate said peaks which have a current insufficient to generate light.

The invention also provides a method of manufacturing a light emitting device comprising applying a layer of optoelectronic material to a hot electron source.

The invention also provides a method of manufacturing a light emitting device comprising:

providing a polycrystalline silicon layer;
oxidising a surface portion of said polycrystalline silicon layer to produce a region of silicon oxide;
applying a layer of electro optical material such as zinc oxide to the silicon oxide.

The invention also provides a method of manufacturing a light emitting device comprising:

providing a substrate such as single crystal silicon;
providing a polycrystalline silicon layer on said single crystal silicon;
oxidising a surface portion of said polycrystalline silicon layer to produce a region of silicon oxide;
applying a layer of electro optical material such as zinc oxide to the silicon oxide.

The invention also provides a method of manufacturing a light emitting device comprising:

providing a polycrystalline silicon layer;
oxidising a surface portion of said polycrystalline silicon layer to produce a region of silicon oxide;
applying a layer of electro optical material such as zinc oxide to the silicon oxide; and
applying to the electro optical material a p-type material such as ITO.

The invention also provides a method of manufacturing a light emitting device comprising:

providing a single crystal silicon substrate;
providing a polycrystalline silicon layer on said single crystal silicon;
oxidising a surface portion of said polycrystalline silicon layer to produce a region of silicon oxide;
applying a layer of electro optical material such as zinc oxide to the silicon oxide; and
applying to the electro optical material a p-type material such as ITO.

Preferably, the method of the present invention provide the step of doping said single crystal silicon and said polycrystalline silicon prior to oxidising the surface of said polycrystalline surface.

The invention also provides a light generating device, such as a display, or a computing device which uses a light emitting structure of the present invention.

### BRIEF DESCRIPTION OF DRAWINGS

FIG. 1 shows a preferred hot electron emitting substrate (HEES) structure of the present invention.

FIG. 2 shows a preferred light emitting sandwich structure of a light emitting structure of the present invention, in conjunction with a source of voltage.

FIG. 3 shows the current vs. voltage (I-V) properties of a HEES of the present invention.

FIG. 4 shows voltage against current for a light emitting structure of the present invention, showing light emitting and non-light emitting regions.

FIG. 5 schematically illustrates states for a light emitting structure according to one embodiment of the present invention.

FIG. 6 illustrates the behaviour of a voltage to light converter of the present invention in time domain where input voltage is changed in four distinctive levels and where the source voltage is 0V.

FIG. 7 shows voltage vs current for a light emitting structure according to one embodiment of the present invention, with a line showing eh underlying increasing trend.

FIG. 8 shows changes in energy states of a HEES of the present invention.

### DESCRIPTION

The invention will now be described with reference to specific embodiments, although it will be appreciated that it will not be limited to those specific embodiments.

A layer of polycrystalline silicon (poly-silicon) is deposited on a substrate or wafer of single-crystal silicon. The polysilicon can be deposited by any suitable means, for example, LPCVD (Low-pressure chemical vapour deposition) at around 600° C. Theoretically, the wafer of single-crystal silicon can be of any thickness. Preferably, because the single-crystal silicon is used as substrate to support the upper structures, normal silicon wafer thickness is used. The thickness of polycrystalline silicon required is preferably sufficient for the polycrystalline oxide to be formed and a layer of poly-silicon to be present under the oxide layer after oxidation. Preferably, the layer of poly-silicon is at least 2 μm thick. The whole is then doped. The single-crystalline silicon and the poly-silicon can either be doped to be n-type (electron conduction) or p-type (hole conduction). However, for best performance, n-type doping to the poly-silicon is normally preferred. The doping must be heavy, i.e. at the level of ˜10¹⁹ cm⁻³ or above.

Any suitable known dopants can be used, for example, the group III or group V elements, such as boron, arsenic, gallium or phosphorus. In n-type silicon wafer, phosphorus is preferably used for doping, with a dopant concentration of at least 10¹⁹ cm⁻³. In p-type wafers, boron is preferably used for doping, with a dopant concentration of at least 10¹⁹ cm⁻³. The doping is preferably carried out by either thermal diffusion or ion implantation. After doping, the dopant is preferably activated, preferably by annealing is needed. The annealing preferably takes place in Ar atmosphere at a suitable temperature.

Once the doped silicon construct is prepared, a very thin layer on the top surface of the poly-silicon is oxidised. The oxidation method used is most preferably wet-oxidation. The wet oxidation of the top poly-silicon layer preferably forms a layer of oxide with thickness of having a lower limit of about 4 nm, more preferably about 6 nm, and independently an upper limit of about 12 nm, more preferably about 10 nm. The oxidation temperature is preferably in the range of 850 to 950° C. to ensure a slow and controllable oxidation process. The duration of the oxidation is relatively short, however, it varies depending on the specification of used equipment. This process produces a layer of silicon dioxide (SiO₂) on the top of the polycrystalline silicone.

It is believed that wet oxidation leads to asperities being formed at the interface of the insulator SiO₂ layer and the polysilicon layer. Asperities are irregular surface projections, of the order of a several angstroms (less than 1 nm), which have small, sharp silicon conducting tips. When a voltage is applied to the structure, it results in an enhancement or amplification of the electric field due to the sharp tips of the asperities, and this in turn serves to produce high energy “hot” electrons.

Whilst polysilicon is the most preferred source of hot electrons, suitable “hot electrons” may also be produced from other types of materials beside polysilicon, for instance, aluminium or magnesium, with the layers of corresponding oxide on top. These tend to be less desirable due to the inherent difficulties in controlling the oxidation of these materials.

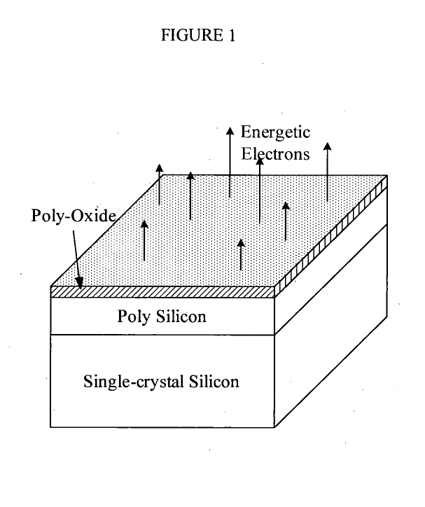

FIG. 1 shows the structure of the first three layers, which serve to produce, under the correct conditions, a flow of energetic (hot) electrons. This sub assembly is the hot electron emitting structure (HEES). From the bottom up, the single crystal silicon serves for supporting the upper structure and the pattern forming on top of it. The single crystal silicon also serves as a source of the electrons, however, as should be noted, it is not the main source of electrons. The heavy-doped poly-silicon is the main source of providing electrons, and is crucial for the asperity formation. The oxidation happens in poly-silicon layer. On top of poly-silicon layer, a thin layer of silicon dioxide is formed.

However other hot energy emitting structures are also possible.

The light emitting structure is then formed by depositing a layer of zinc oxide (ZnO) or other optoelectronic materials such as InP and GaN on top of the (HEES). ZnO is generally chosen as the candidate optoelectronic material as it makes the structure simple and inexpensive to fabricate.

ZnO has a wide bandgap that requires high energy to emit light. On HEES's, the ZnO successfully emits light, which demonstrates that the HEES is able to provide sufficiently high energy to drive the process. Therefore, it would be expected that any other optoelectronic material (direct-band) that had a narrower bandgap than ZnO could be used in conjunction with a suitable HEES as a light emitting structure. Other optoelectronic materials, for example, could be GaN, InP, GaAs, etc.

The ZnO layer may be placed on the HEES using any conventional method. The simplest methods are either conventional Sol-Gel methods or magnetron sputtering. Depending on the desired emitting properties of ZnO including wavelengths and intensities, other methods such as LECVD and MBE can be used to deposit ZnO. When using magnetron sputter to deposit a thin layer of ZnO, either DC or radio frequency (RF) current can be used, depending on the structure and thickness required. Processing parameters such as the working atmosphere and deposition current density can also be varied to control the required properties of the ZnO layer.

ZnO is an important semiconductor material with many unique properties and potential applications. The photoluminescence spectrum of ZnO has been investigated and it emits light in the range of UV, green and red. However, the electroluminescence properties of ZnO have not been well reported due to its wide energy bandgap (3.37 eV). In order to emit light from ZnO using electricity, a ZnO p-n junction or high energy electrons are needed. However, p-type ZnO is not easy to achieve, nor is it easy to obtain high energy electrons that can readily be injected into ZnO, especially from integrated circuits.

The ZnO layer may be of any thickness, but is preferably between 200 nm and 1000 nm. The ZnO may be n-type (electron) or p-type (holes) if it is doped for example with excess aluminium, indium or nitrogen. The intrinsic band gap for ZnO is 3.37 eV, corresponding to the UV emission. However, ZnO often contains structural defects, and can be doped to have a reduced band gap, resulting in visible light emission with controlled wavelength (colour).

Because the emitting light is from the ZnO itself by electron-hole recombination, either p- or n-type ZnO can be used. However, if a ZnO p-n junction can be realized and put in conjunction with a HEES, the light emission performance will be further enhanced.

Without wishing to be bound by theory, it is believed that the energy from hot electrons generated from the asperities in the HEES is injected into the ZnO layer. Because the electrons are of such high energy (this can be proved by HEES' electrical properties—the lowered potential barrier is about 1.8 eV compared to the normal 3.02 eV), they are sufficient to cause electron-hole recombination in ZnO. This leads to excitation of photons from the ZnO, and as a consequence the ZnO layer emits light.

The thickness of ZnO layer influences the output light intensity, while the composition/defect structure of ZnO controls the output light colour (wavelength). However, from the experimental results, the voltage that starts the visible light emission does not change with the thickness of ZnO, which is a fundamental property of the optoelectronic material.

Therefore, the structure, composition and thickness of the ZnO layer can be adjusted to control the light intensity and wavelength independently. Depending on the structure, thickness and manner of deposition of the ZnO layer, various light emitting units such as visible light sources and lasers can be provided.

For instance, when a porous ZnO layer is used, the structure acts as a ZnO electroluminescent light laser. The porous ZnO can be used to form a cavity and will allow the preparation of a VCSEL (vertical-cavity surface-emitting laser) unit based on the structures of the present invention to be made on silicon.

Red and green light may be observed by varying ZnO processing parameters and compositions. Preliminary electroluminescent experiments with the above sandwich structures, led to the emission of red and green light using a simply-processed and deposited ZnO layer. The ZnO properties can be varied by different means, such as doping, sputtering techniques, quantum dots, size, etc. For example, when the deposited ZnO is annealed in oxygen atmosphere for different annealing times, the output light wavelength (colour) changes. Annealing for a short time tends to produce a structure which emits red light, whereas longer annealing leads to structures that emit green light.

It is possible to enhance the performance of the device by the addition of a further layer of p-type material on top of the ZnO. A layer of indium tin oxide (ITO) may be deposited on top of the ZnO layer. ITO is transparent over a wide range of thickness. In light emitting applications, the thickness of ITO is preferably controlled to less than 200 nm and never exceeds 500 nm. Without the addition of any further topping layers, ITO alone is sufficient to be used as the electrode that the voltage can be directly applied to as it has good conductivity. The ITO layer is here used only as an electrode, so it may be deposited by any means, for example, by magnetron sputtering.

It is believed that because ITO is a hole donor, it enhances the electron-hole recombination and increases intensity of generated light.

The addition of ITO also has additional benefits. It serves as a transparent electrode layer, over the top of the ZnO, to which a voltage is applied. The light generated from the underlying ZnO layer is visible through the ITO electrode.

It has also been observed that the use of ITO significantly decreases the voltage needed to start the light emission, yet at the same time significantly increases the overall breakdown voltage of the device.

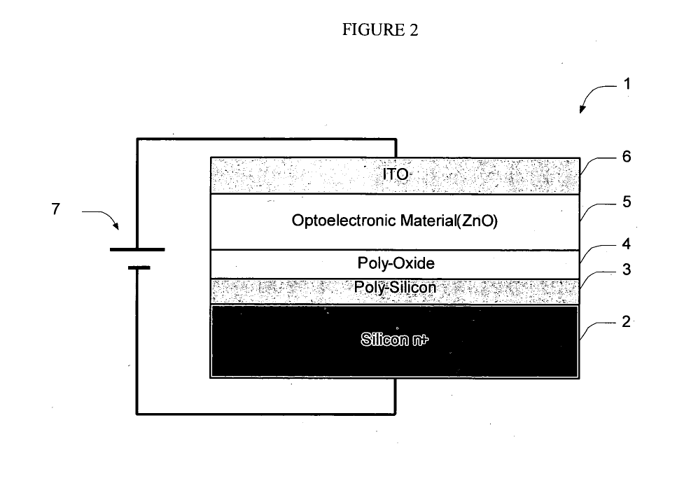

As such, the ITO layer is highly suitable for various optoelectronic applications. The most preferred light emitting structure of the present invention is the sandwich structure HEES-ZnO-ITO shown in FIG. 2.

FIG. 2 illustrates a light emitting structure 1 according to one embodiment of the present invention. Structure 1 includes an n-type silicon substrate 2, onto which a heavily doped poly-silicon layer 3 is deposited. A thin oxide layer 4 is added to the poly-silicon layer, for example by way of wet oxidation. Such a structure provides hot electrons through FN tunnelling. An optoelectronic material 5, in the present example being ZnO, is deposited on top of oxide layer 4. Finally, a further layer of p-type material 6 such as ITO is sputtered on top of optoelectronic material 5. Voltage is able to be applied between ITO layer 6 and silicon substrate 2, for example by way of a source 7.

Other types of top layer electrodes, e.g. Al or Au can be used, but the utilisation of ITO as the top layer electrode provides the most satisfactory performance properties for the light emitting device. The ITO layer also serves to protect the light emitting layer from contamination, oxidation, nitiridation and other similar unwanted effects.

The whole construct in its most preferred form can thus be thought of as a sandwich of ZnO between a source of hot electrons (poly silicon/silicon dioxide) and a source of additional holes (ITO). The sandwich structure enables recombination of hot electrons and holes and the generation of light.

When a voltage in range from 4 V and 18 V is applied across the sandwich structure, light is generated. The wavelength of the light varies based upon the structure and composition of the ZnO layer.

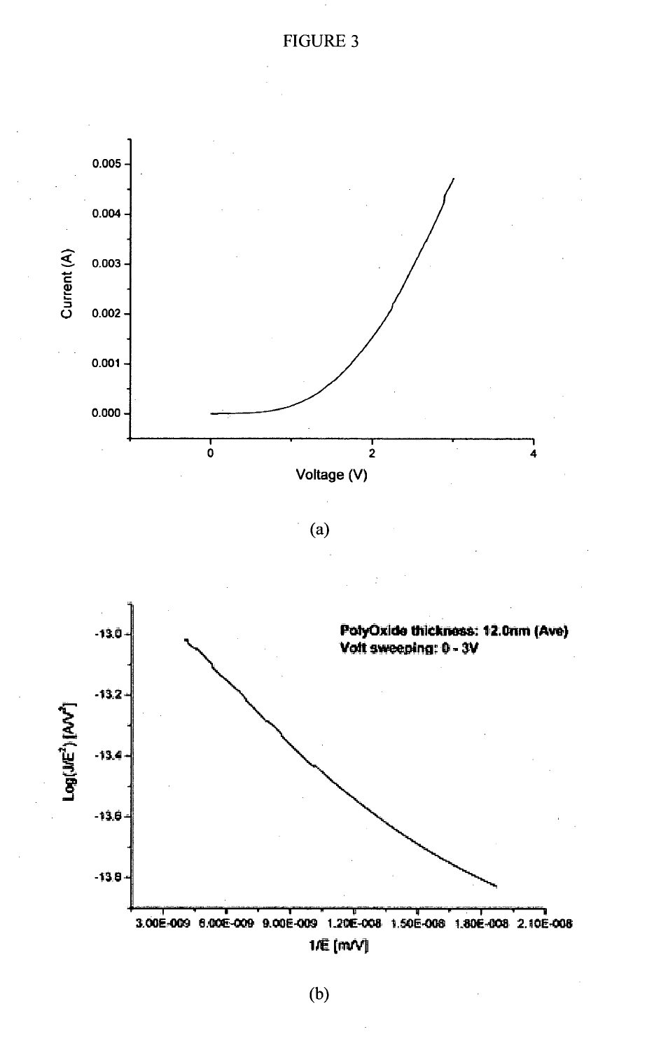

The current and voltage (I-V) properties of the substrate were examined and exhibit the Fowler-Nordheim effect. FIG. 3(a) shows the relation ship between I-V for a HEES of the present invention and FIG. 3(b) shows the transformed curve according to Fowler-Nordheim theory. These demonstrate that the HEES generates the hot electrons.

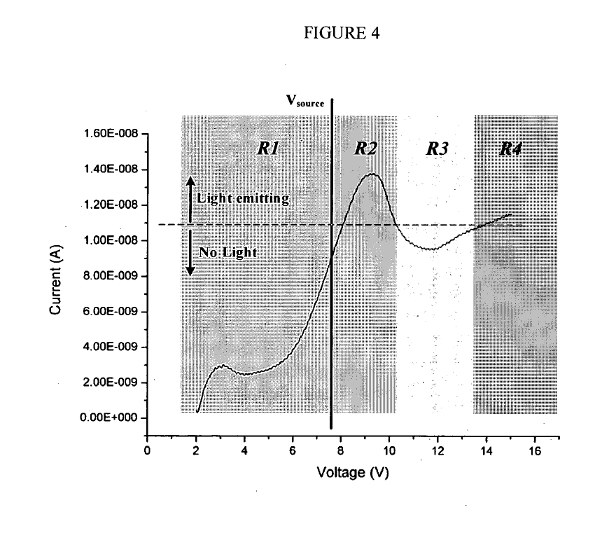

Additionally, experiments conducted in respect of a light emitting structure corresponding to structure 1 over a wider range of voltages V have revealed the phenomenon illustrated in FIG. 4. During the gradual increase of applied voltage, light appears (i.e. light can be observed) when the voltage reaches a certain level. Further increase of voltage causes a corresponding increase of the light intensity until voltage reaches another level when the light disappears. By further increasing the voltage, the light re-appears at another voltage threshold after which the light is present until the voltage increases to another threshold when the light disappears again. The correspondence of applied voltage and light appearance on the I-V curve is shown in FIG. 4. Based on presence/absence of the light, it is possible to divide the I-V curve into four regions, R1-R4.

Based on FIG. 4, it can be readily appreciated that the emission of light is able to be controlled by varying the applied voltage. Region R1 corresponds to a state where there is no light due to insufficient current flow and lack of sufficient hot electron energy. Region R2 corresponds to a state where light is emitted. In region R3, light is not emitted due to a decrease in electron energy (as compared with region R3). Light reappears in region R4.

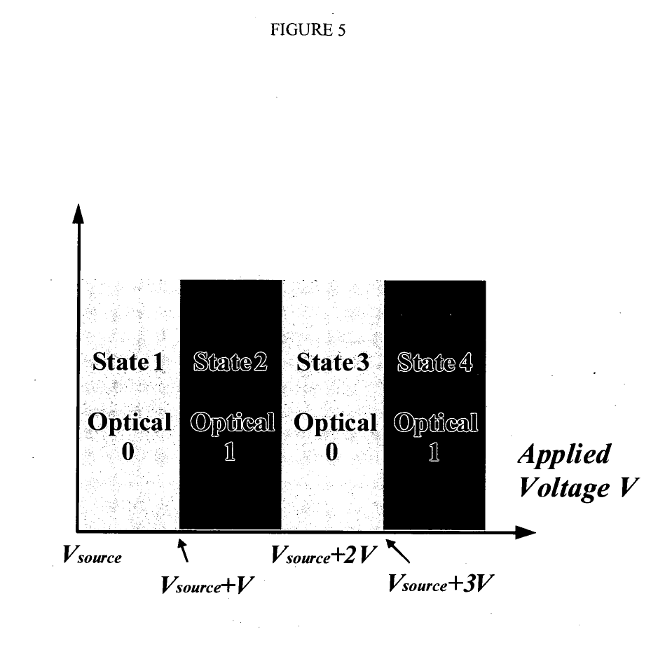

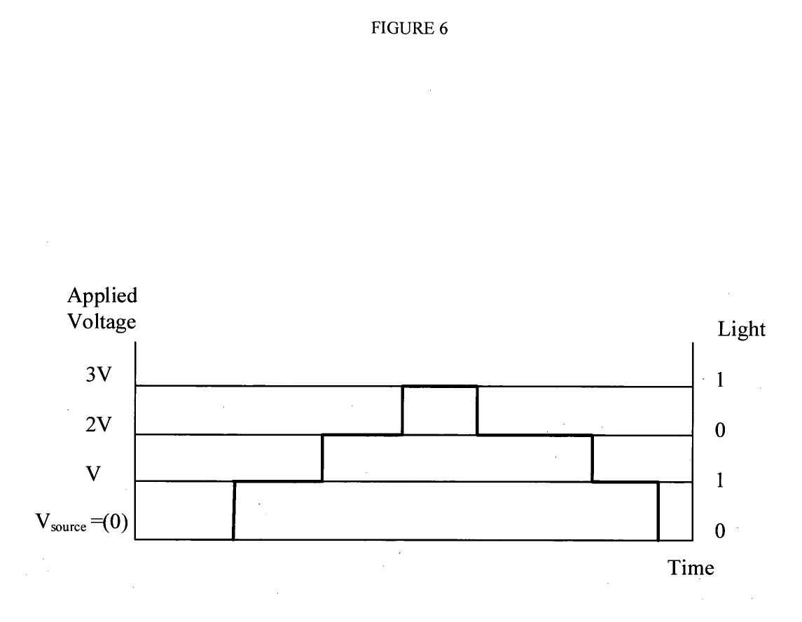

FIG. 5 shows schematically that the devices of the present invention provide alternating off-on states as voltage is increased. FIG. 6 shows a schematic as the voltage is increased over time.

As can be seen, the light emitting structure of the present invention is relatively simple and inexpensive; and the layered constructs can be prepared by processes usually regarded as standard in the preparation of semiconductor integrated circuits.

The feature size of asperities is in the atom scale. The asperities are formed by a few, up to tens of atoms. From this aspect, they are much smaller than the currently available light emitting units or laser units which are at least hundreds of microns. Therefore, the light emitting unit or the laser can be made very small if desired.

The light emitting structure and the fabrication techniques thereof are fully scaleable to be compatible with the existing semiconductor devices and Si-CMOS (Complementary metal-oxide-semiconductor) and MEMS (Micro-Electro-Mechanical Systems) fabrication processes, meaning they can be readily merged with aspects of existing technology. The light emitting units of the present invention can be fabricated onto a standard IC, which further can be used in applications such as light emitting elements and one- and two-dimensional arrays, communication links (such as between parts of an IC), all of which help make feasible optically based computation and information processing. Other uses, such as new types of sensors based on small scale lasers, are also envisaged.

The light emitting structure can be implemented on a very small area and multi-light source which have different wavelengths, intensities, phases, incident directions, and so on can be realized on a single chip.

Previously, white light emission has been dominated by the Japanese phosphor, the exact composition of which has been kept strictly secret. The light emitter of the present invention allows the wavelength of the light to be adjusted (controlled) by the design of the ZnO layer. White light emission is achievable by placing RGB light emitters in a very small area (block). Red, green and blue emissions may be achieved by processing control and doping. Therefore, the present invention opens a new field of white light emission. The present invention is not based on a p-n junction structure, so it also opens the door to research on non-p-n junction light emissions and new types of light emission devices.

### Example 1

The light emission performance of the present device with a Sol-Gel prepared ZnO layer and a top electrode of Au was determined. The thicknesses of ZnO and Au are 700 nm and 300 nm, respectively. The ZnO is deposited at the whole area of the sample (1.5 cm×1.5 cm) and the Au electrode is a round plate of 1 mm diameter. The light emission was observed under microscope and with the naked eye. The light starts emitting at an applied voltage of 9.5 V, and emits up to the breakdown voltage of the device at 13 V. The device yielded yellow and red light.

### Example 2

The light emission performance with a magnetron-sputtered ZnO layer and a top electrode of ITO was determined. The thickness of ZnO varies from 200 nm to 2 μm. The thickness of ITO is from 200 nm to 300 nm. The ZnO is sputtered at the whole surface of the sample while the ITO electrode is a round plate of 1 mm diameter. From the experiments, the samples with a ZnO thicknesses in the range of 300 nm to 700 nm and ITO thicknesses of 200 nm have the best light emitting performance relative to other devices. The light emission was stronger than that observed for the Sol-Gel ZnO/Au setting. The starting light emitting voltage was 5.7 V as observed by the naked eye and continued to the breakdown voltage of the device at 18 V. The starting emission voltage is lower and the breakdown voltage is also significantly higher than for the Sol-Gel ZnO/Au device. The device provides light of a wavelength of 520 nm (Green) and 620 nm (Red) electroluminescence. A weak emission of UV light is also observed.

This system is very stable in ambient pressure and temperature, which is a significant improvement over other electroforming devices which are reported to last from around 3 hrs to at most 2 days. The devices of the present invention are found to be very stable with respect to the time, and no apparent degradation has been observed during the course of the research thus far.

As mentioned above the Hot Electron Emitting Substrate (HEES) of the present invention exhibits a phenomenon which can be referred to as “double tunnelling”. At ambient atmospheres and at room temperatures, the I-V characteristic of HEES shows two current peaks during voltage sweep from 2V to 15V. Without wishing to be bound by theory, the two current peaks are believed to indicate two different tunnelling processes, Fowler Nordheim (FN) tunnelling and a tunnelling diode mechanism which occur at two different voltage ranges.

To examine the double tunnelling of the HEES, a layer of poly-crystalline silicon (poly-Si) was deposited on an n-type single-crystalline silicon wafer, and heavily doped with Boron at the level of ˜1×10¹⁹ cm⁻³. A very thin layer of silicon dioxide (SiO₂) was formed on the poly-Si by wet-oxidation. The single-crystalline silicon supports the upper layers and makes the contact with the electrode for testing.

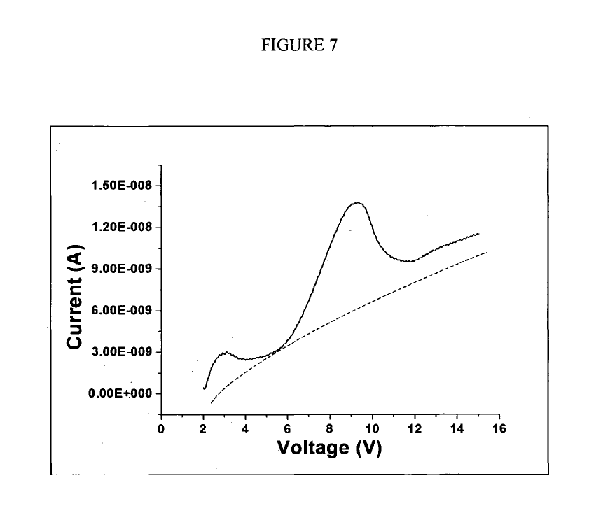

A layer of electrode was then deposited on the SiO₂. In one embodiment, an aluminium film was applied which is deposited with a metal mask to form a circular 300 nm thick Al plate of 1 mm diameter, which serves as an anode. The sample is placed on a metal plate which is used as a cathode. As the doped single-crystalline silicon wafer is conductive, the contact between the metal plate and single-crystalline silicon wafer has good conductivity. A voltage is applied between the cathode and a probe tip which contacts the Al anode. The testing was conducted at room temperature and in ambient atmosphere in a dark environment to avoid the possibility of photo stimulated electron emission. The voltage was swept from 2 V to 15 V with the step of 0.02 V. The resulting I-V curve is shown in FIG. 7. FIG. 7 shows clearly two current peaks. The current increases nonlinearly with the voltage in the beginning, and reaches the first current peak at around 3 V. Then the current drops a little and starts increasing again at around 4.5 V. At around 9 V, the second current peak is identified. Then the current decreases again, and resumes increasing at around 12V. Apart from the two peaks, the curve keeps a steady increase trend as shown by the dashed line in FIG. 7.

As indicated above, the two current peaks are believed to be the result of two different tunnelling processes. In lower voltage range, the first current peak exhibits the properties of FN Tunnelling while in the higher voltage range the mechanisms of Tunnelling Diode can be used to explain the second current peak.

In FN Tunneling, only the electrons with energy sufficient to surmount the surface potential barrier are able to tunnel through the insulating layer and escape from the condensed phase. This can happen if two conditions are satisfied: (1) electrons have to be energetic (have high energy) and (2) the insulating layer through which electrons are to tunnel has to be thin enough that the electrons are not trapped in it. In the HEES structure of the present invention, the silicon dioxide is preferably present in a very thin layer (6 to 12 nm).

In FN Tunneling, the current density J increases exponentially with the applied electric field E [1]:

$$\begin{matrix}J = {K}_{1} \cdot {E}^{2} exp ( - \frac{{K}_{2}}{E} ) \\ where & ( 1 ) \\ {K}_{1} = 1.5413 \times {10}^{- 6} \cdot \frac{{m}_{o}}{{m}_{ox}} \frac{1}{φ} \\ {K}_{2} = 6.828 \times {10}^{7} \cdot \sqrt{\frac{{m}_{ox}}{{m}_{o}}} \cdot {φ}^{3 / 2} & ( 2 )\end{matrix}$$

In (2), φ is the barrier height between the semiconductor and insulator, mₒ is the effective mass of an electron, and mₒₓ is the effective electron mass in oxide layer. Mₒₓ=0.5 mₒ [3].

To distinguish the FN tunnelling from other I-V properties which also exhibit the exponential relationship between voltage and current, a transformation of equation (1) is taken as shown in (3).

$$\frac{d ( log ( J / {E}^{2} ) )}{d ( 1 / E )} = - k {φ}^{3 / 2} \\ where , \\ k = \frac{4}{3} \cdot \frac{\sqrt{2 {m}_{ox} q}}{ℏ \sqrt{{m}_{o}}} / ln ( 10 ) , \qquad ( 3 )$$

q=1.6×10⁻¹⁹, C is the electron charge and h=6.58×10⁻¹⁶ eV·s is the Reduced Planck Constant

From (3), the relation between log(J/E²) and 1/E is obtained as a straight line with negative slope −kφ^{3/2}, which is used to characterize the FN tunnelling.

To verify the FN Tunneling feature of HEES, the voltage was swept from 0 V to 3 V. The I-V curve of a typical HEES sample is shown in FIG. 3(a).

Based on equation (3), the transformation of the curve is done under the following conditions: J=I/A and E=V/d, where I is the collected current, V is the applied voltage, A is the area of the Al anode with a radius r=0.5 mm, and the thickness of SiO₂ d=12 nm. The result in FIG. 3(b) shows an approximately straight line with negative slope, indicating the FN effect. Because the thickness of the silicon dioxide is not uniform due to the fabrication process, this analysis uses an approximate value of the potential barrier height and electric field (which actually varies from point to point under the same electrode). The potential barrier obtained from the curve in FIG. 3 by using [3] is 3.3 eV. Because the thickness of SiO₂ was 12 nm, the tunnelling phenomenon presented above can not be explained as direct tunnelling, which requires smaller SiO₂ thickness (<4 nm), but rather as FN tunnelling. Due to the FN tunnelling, the electrons tunnelled through SiO₂ provide an additional current component to the normal current flow. This additional current contributes to the overall abrupt current increase in the beginning. Then, according to FIG. 7, the current drops and forms the first current peak. The reason for the drop of the current is still not clear. Without wishing to be bound by theory, the present applicant believes that changes in the material such as electroforming may have occurred, which causes the current to drop at this voltage level before it starts to increase again.

Turning to the second peak, it is known that by implementing a very thin p-n junction, electrons are tunnelled from the valence band of p-side to the conduction band of n-side. This electron tunnelling phenomenon is the basis of the tunnelling diode. It results in a current peak formed when the voltage is increased. Although HEES is not a p-n junction, similar reasoning can be used to explain its behaviour at the higher voltage range where the second current peak appears.

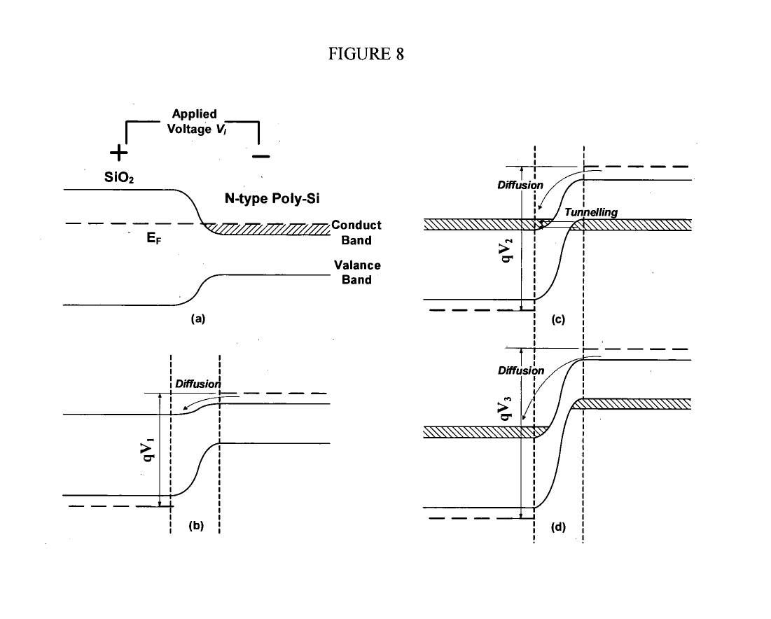

In FIG. 8, item (a) shows the initial energy band structure state when HEES structure is formed. The behaviour of HEES structure is analysed when the voltage is applied from silicon dioxide side (anode) to poly-Si side (cathode). In FIG. 8, items (b-d), q stands for the electron charge, while Vᵢ (i=1, 2, 3) is the voltage applied to HEES. When the voltage increases, because the poly-Si is heavily doped, the electron energy band in the poly-Si side moves up relative to the energy band of silicon-dioxide. With further increase of the voltage (V₁), electron diffusion starts to occur when it reaches the state as shown in FIG. 8, item (b). When the applied voltage increases to a certain level V₂, the energy band comes to the state as shown in FIG. 8, item (c). In this state the electrons in the valence band in doped poly-Si get enough energy to match the conduction band energy states in silicon dioxide, resulting in electron tunnelling from the doped poly-Si into silicon dioxide through the thinned band gap. At this stage, both electron diffusion and tunnelling are simultaneously present, resulting in an abruptly increased current. However, when the voltage increases further to V₃ (FIG. 8, item (d)), the energy states become mismatched, electron tunnelling stops, and the current drops. Thus, the second current peak is formed. From this point on, electron diffusion dominates the transportation of electrons in HEES.

Thus, without wishing to be bound by any specific theoretical interpretation for the observed phenomena, the applicants suggest that the two tunnelling effects as explained above are the main contributors to the current peaks in I-V curve of HEES structure, which they have “the double tunnelling effect”. Since tunnelling needs an amplified electric field, it appears that an electric field amplification mechanism is operative within the HEES structure. It is believed that very small and sharp conductive tips (asperities) formed at the interface area between poly-Si and SiO₂ during the fabrication processes amplify and accelerate electrons under an applied electric field.

The devices of the present invention are potentially useful in a number of applications, including:

Controllable silicon-based displays that can emit light of different wavelengths including white light, for use in lighting and display devices; On-chip lasers, and devices such as VCSEL's (vertical-cavity surface-emitting lasers); As a light source for on-chip communication and optoelectronic integration and for sensing applications (micro optical-electro-mechanical systems, MOEMS); and optical logic elements as the basis of optical computing and information processing.

1.-28. (canceled)

29. A light emitting structure comprising a hot electron source and a layer of optoelectronic material disposed thereon; and wherein the hot electron source comprises a single crystal silicon substrate, a polycrystalline silicon layer disposed thereon, and a layer of silicon oxide disposed on the polycrystalline silicon layer.

30. The light emitting structure according to claim 29 further comprising p-type material disposed on the optoelectronic material.

31. The light emitting structure according to claim 29 wherein the hot electron source comprises a single crystal silicon substrate having an aluminium or magnesium layer disposed thereon, with a corresponding layer of aluminium oxide or magnesium oxide disposed on the aluminium or magnesium layer.

32. The light emitting structure according to claim 30 wherein the hot electron source comprises a single crystal silicon substrate having an aluminium or magnesium layer disposed thereon, with a corresponding layer of aluminium oxide or magnesium oxide disposed on the aluminium or magnesium layer.

33. The light emitting structure according to claim 29 wherein the optoelectronic material is ZnO.

34. The method according to claim 30 wherein the p-type material is indium tin oxide (ITO).

35. A light emitting structure that comprises, in order, the following layers:
a single crystal silicon substrate;
a polycrystalline silicon layer;
a silicon dioxide layer; and
a zinc oxide layer.

36. The light emitting structure according to claim 35 that comprises, in order, the following layers:
a single crystal silicon substrate;
polycrystalline silicon layer;
a silicon dioxide layer;
a zinc oxide layer; and
an indium tin oxide (ITO) layer.

37. The light emitting structure according to claim 35 wherein the single crystal silicon substrate and the polycrystalline silicon layer are doped such that they are both n-type or p-type doped.

38. The light emitting structure according to claim 37 wherein the single crystal silicon substrate and the polycrystalline silicon layer are heavy doped.

39. The light emitting structure according to claim 37 wherein the single crystal silicon substrate and the polysilicon layer are both heavy doped to be n-type silicon.

40. The light emitting structure according to claim 37 wherein the single crystal silicon substrate and the polysilicon layer are both heavy doped to be or p-type silicon.

41. The light emitting structure according to claim 29 that displays a current vs voltage curve that has a current at a predetermined voltage sufficient to generate light.

42. The light emitting structure according to claim 29 that displays at least one current peak on a current vs voltage curve that has a current at a predetermined voltage sufficient to generate light.

43. The light emitting structure according to claim 29 that displays two current peaks on a current vs voltage curve, that has a current at two predetermined voltage sufficient to generate light and a region intermediate said peaks which has a current insufficient to generate light.

44. The light emitting structure according to claim 29 that displays multiple current peaks on a current vs voltage curve, wherein the peaks corresponds to the predetermined voltage, and wherein there are regions intermediate said peaks which have a current insufficient to generate light.

45. A method of manufacturing a light emitting device comprising applying a layer of optoelectronic material to a hot electron source, wherein the hot electron source comprises a single crystal silicon substrate, a polycrystalline silicon layer disposed thereon; and a layer of silicon oxide disposed on the polycrystalline silicon layer.

46. A method of manufacturing a light emitting device comprising:
providing a single crystal silicon substrate;
providing a polycrystalline silicon layer on said single crystal silicon;
oxidising a surface portion of said polycrystalline silicon layer to produce a region of silicon oxide;
applying a layer of electro optical material such as zinc oxide to the silicon oxide.

47. The method of manufacturing a light emitting device according to claim 46 comprising:
providing a single crystal silicon substrate;
providing a polycrystalline silicon layer on said single crystal silicon;
oxidising a surface portion of said polycrystalline silicon layer to produce a region of silicon oxide;
applying a layer of electro optical material such as zinc oxide to the silicon oxide; and applying to the electro optical material a p-type material.

48. The method of manufacturing a light emitting device according to claim 46 wherein oxidising a surface portion of said polycrystalline silicon layer is by wet oxidation.

49. The method of manufacturing a light emitting device according to claim 47 wherein the p-type material is ITO.

50. The method according to claim 46 comprising the step of doping said single crystal silicon and said polycrystalline silicon prior to oxidising the surface of said polycrystalline surface.

51. A light generating device which uses a light emitting structure according to claim 29.

52. The light generating device according to claim 51 in the form of a display or a computing device.
